(19) United States
(12) Patent Application Publication
(10) Pub. No.: US 2006/0278871 A1
(43) Pub. Date: Dec. 14, 2006

(54) Detecting and improving bond pad connectivity with pad check

(76) Inventors: Shailesh Hegde, Cary, NC (US); Peter Baader, Munich (DE); Tilman Neunhoeffer, Unterhaching (DE); Hans-Ulrich Armbruster, Unterhaching (DE)

Correspondence Address: PATTERSON & SHERIDAN, LLP;Gero McClellan / Infineon Technologies, 3040 POST OAK BLVD.,, SUITE 1500, HOUSTON, TX, 77056, US

(21) Appl. No.: 11/147,541

(22) Filed: Jun. 8, 2005

(51) Int. Cl. H01L 23/58

(52) U.S. Cl. 257/48

(57) ABSTRACT

A method for analyzing an integrated circuit (or constituent parts thereof), a computer program implementing the method, and a computer configured to execute the program is disclosed. Analyzing the integrated circuit may include retrieving a design for the integrated circuit from a layout database, identifying the bond pads and gates included in the design of the integrated circuit, determining the connections between the bond pads and the gates, and determining whether a connection between a particular gate and a particular bond pad lacks a connection segment routed over a required layer.

### CROSS REFERENCE TO RELATED APPLICATIONS

This application is related to commonly assigned, published U.S. patent applications “Method of Analyzing an Integrated Electric Circuit, Computer Program Utilizing the Method, Data Carrier Including the Method, and Method for Downloading the Program,” U.S. Publication No. 2003/0030445, and “Method for Checking an Integrated Electrical Circuit,” U.S. Publication No. 2003/0159120, both of which are incorporated by reference herein in their entirety.

### BACKGROUND OF THE INVENTION

1. Field of the Invention

The invention generally relates to an automated method for testing the design of an integrated circuit (IC). Specifically, embodiments of the invention may be used to identify faults in the design of an IC related to an improper connection between a bond pad and other elements of the IC, such as a gate.

2. Description of the Related Art

Integrated circuits are typically manufactured by building a sequential series of layers on a substrate. During this process, electrostatic charges may accumulate on parts of an IC as it is being manufactured. For example, during an ion deposition process, etching may cause an electrical charge to accumulate on the bond pads of an IC. The “antenna effect” is a common name for the effects of charge accumulation in isolated nodes of an integrated circuit during its processing. This phenomenon may occur regardless of the specific manufacturing process used by a particular manufacturer.

If a sufficient electrostatic charge accumulates on a component of an IC, then during a subsequent rapid discharge, the IC may be damaged. Often, if an accumulated charge is not dissipated over a sufficiently wide metal layer, then the gates of an IC being manufactured may be damaged or destroyed. Thus, for these manufacturability reasons related to the IC fabrication process, a bond pad must not be directly connected to a gate, unless the connection passes through certain metal layers. Accordingly, prior to being manufactured, the design of an IC must be evaluated to determine whether any bond pad is connected to a gate through a connection that is not properly routed through a sufficiently wide metal layer.

Given that it often takes weeks or months to manufacture an integrated circuit, it is typical for designers to spend substantial time analyzing a design layout to avoid costly mistakes. Furthermore, it can be difficult, if not impossible, to correct an IC design flaw, once the IC has been manufactured.

Current systems test bond pad connectivity by reviewing a printout of an IC design, or by reviewing a representation of the design on a computer screen extracted from a layout database. The connections from each bond pad are inspected to determine whether the bond pad is connected to a gate without being routed through a required layer (e.g., metal 2). However, this type of manual inspection is both prone to errors and time-consuming. Furthermore, the probability of an error increases with the complexity or integration level of an IC.

Accordingly, there is a need for a method for detecting and improving bond pad connectivity. Further, the method for detecting improper bond pad connectivity should not rely on a manual inspection of the connections between each bond pad and the gates of an integrated circuit.

### SUMMARY OF THE INVENTION

Embodiments of the invention generally provide a method for analyzing an IC, a computer program implementing the method, and a computer configured to execute the program. Embodiments of the invention identify faults in the design of an IC by identifying connections between a bond pad and the gates of an integrated circuit that are not routed through a required intermediate layer.

One embodiment of the invention provides a method for analyzing bond pad connectivity in the design of an integrated circuit. The method generally includes retrieving the design for the integrated circuit from a layout database, identifying the bond pads and gates included in the design of the integrated circuit, and determining the connections between the bond pads and the gates. The method generally further includes determining whether a connection between a particular gate and a particular bond pad lacks a connection segment routed over a required layer. After determining the improper connections, a report is generated identifies the particular bond pad and particular gate that are connected without a connection over the required layer.

Because the Metal 2 layer, for example, is often wide enough to dissipate electrical charges that accumulate during the IC manufacturing process, the required layer may be second metal layer of the integrated circuit. Additionally, to identify an inappropriate connection, the method may include, extending the design of the integrated circuit to include an additional layer interpolated between the required layer and a layer immediately below the required layer, selecting the particular bond pad for analysis, removing the required layer from the design of the integrated circuit, and determining whether a connection path exists between the additional layer and the particular bond pad in the design of the integrated circuit, after the required layer is removed. If so, then the connection is improper and added to a report of improper connections. Additionally, in one embodiment, selecting the particular bond pad for analysis may include selecting only bond pads that are not identified by the design layout as belonging to certain user defined nets (e.g., power nets).

Another embodiment provides a computer readable medium, containing a program which, when executed on a computer system, performs an operation for analyzing bond pad connectivity in the design of an integrated circuit. The operation generally includes retrieving the design for the integrated circuit from a layout database, identifying the bond pads and gates included in the design of the integrated circuit, determining the connections between the bond pads and the gates, and determining whether a connection between a particular gate and a particular bond pad lacks a connection segment routed over a required layer. In this illustrative embodiment the program may be a driver script configured to interact with a layout database and a design rule checker application by executing a plurality of runsets.

Another embodiment provides a method for analyzing the bond pad connectivity in the design of an integrated circuit. The method generally includes, executing a first runset configured to generate a regular extraction of an integrated circuit, from the design of the integrated circuit stored in a layout database, executing a second runset configured to extract the bond pad and gate locations from the regular extraction, executing a third runset configured to identify the connections between the bond pads and gates extracted by the second runset, and executing a fourth runset configured to determine whether any of the connections between a particular bond pad and a particular gate lack a connection routed over a required layer. In one embodiment, the runsets may be executed by a driver script configured to interact with the layout database, a database extraction tool and a rule checker application. Alternatively, a designer may interact with the layout database, database abstraction tool and the rule checker application directly to invoke the required runsets.

Additionally, in this illustrative embodiment, the fourth runset may be configured to (i) extend the design of the integrated circuit to include an additional layer interpolated between the required layer and a layer immediately below the required layer, (ii) select a particular bond pad for analysis, (iii) remove the required layer from the design of the integrated circuit, (iv) determine whether a connection path exists between the additional layer and the particular bond pad in the design of the integrated circuit after the required layer is removed, and (v) if so, generate a report indicating an improper connection for the particular bond pad present in the design of the integrated circuit.

Another embodiment of the invention provides a computer readable medium containing a program which, when executed on a computer system, performs an operation for analyzing bond pad connectivity in the design of an integrated circuit. The operation generally includes, executing a first runset configured to generate a regular extraction of an integrated circuit, from the design of the integrated circuit stored in a layout database, executing a second runset configured to extract the bond pad and gate locations from the regular extraction, executing a third runset configured to identify the connections between the bond pads and gates extracted by the second runset, and executing a fourth runset configured to determine whether any of the connections between a particular bond pad and a particular gate lack a connection routed over a required layer.

Another embodiment provides a computer system for identifying improper connectivity between a bond pad of and a gate in a design of an integrated circuit. The computer system includes a layout database storing the design of the integrated circuit, a database extraction tool, a design rule checker application, and a driver script configured to execute a plurality of runsets to determine whether any of the connections between a particular bond pad and a particular gate of the integrated circuit design lack a connection routed over a required layer.

The plurality of runsets may be configured as required to (i) extend the design of the integrated circuit to include an additional layer interpolated between the required layer and a layer immediately below the required layer, (ii) select a particular bond pad for analysis, (iii) remove the required layer from the integrated circuit design, (iv) determine whether a connection path exists between the additional layer and the particular bond pad in integrated circuit design, after the required layer is removed, and (v) if so, generate a report indicating an improper connection for the particular bond pad present in integrated circuit design.

### BRIEF DESCRIPTION OF THE DRAWINGS

So that the manner in which the above recited features of the invention can be understood, a more particular description of the invention, briefly summarized above, may be had by reference to the exemplary embodiments illustrated in the appended drawings. Note however, that the appended drawings illustrate only typical embodiments of this invention and should not, therefore, be considered limiting of its scope, for the invention may admit to other equally effective embodiments.

FIG. 1 is a functional block diagram illustrating a system for testing an integrated circuit, according to one embodiment of the invention.

FIGS. 2A and 2B illustrate a three-dimensional (3D) perspective of a first and second integrated circuit design extracted from a layout database, according to one embodiment of the invention.

FIGS. 3A and 3B illustrate a two-dimensional plan view of the integrated circuit designs first illustrated in FIGS. 2A and 2B, according to one embodiment of the invention.

FIGS. 4A and 4B illustrate a modified view of the integrated circuit designs first illustrated in FIGS. 3A and 3B, with an additional layer added to the integrated circuit, according to one embodiment of the invention.

FIGS. 5A and 5B illustrate a view of the integrated circuit design illustrated in FIGS. 4A and 4B, with a layer of the integrated circuit design removed from the integrated circuit, according to one embodiment of the invention.

FIG. 6 illustrates a method for testing the design of an integrated circuit, according to one embodiment of the invention.

FIG. 7 illustrates a method detecting improper bond pad connectivity present in the design of an integrated circuit, according to one embodiment of the invention.

### DETAILED DESCRIPTION OF THE PREFERRED EMBODIMENTS

Embodiments of the invention generally provide an improved method for testing the design of an integrated circuit (IC). An automated layout check analyzes the design to determine which bond pads are connected to gates that are not also routed over certain required metal layers. By running this check prior to the tape-out, bond pad connections may be improved.

A bond pad is typically defined by a metal region on one surface of an IC that is used to create an electrical connection to an external circuit, e.g., by means of a bond wire. Thus, the bond pad acts as an interface between the IC and the external world. Embodiments of the invention provide automated techniques for examining the bond pads of an IC design, and their connections to internal components of the IC (e.g., gates). In one embodiment the method may be implemented as a computer program configured to perform an automated check on the design of an IC stored in a layout database. Once the check is completed, a report is generated with details about the bond pads of the IC, and connections to gates that are not routed through certain metal layers. Because pre-defined power nets are normally routed with sufficient width to dissipate electrical charges that may accumulate during the manufacturing process, they may be excluded from this check.

Using information from the generated report, an IC designer can then improve the layout and ensure that the correct connections are made between bond pads and gates of the IC. In one embodiment, runsets are used for identifying and checking bond pads, gates and their connections. A driver script may be used to retrieve the IC design from the layout database to be processed for these runsets. The runsets used may include a runset for the extraction of bond pads, a runset for the extraction of gates, a runset for the identification of connections from bond pads to gates, and a runset for the determination of segments in connections from bond pads to gates that are not routed through a required layer (e.g., metal 2). The driver script takes extraction generated by the layout database runset and provides it to a design rule checker that executes runsets for the automated check.

In one embodiment, the invention, and associated runsets, may be implemented using computer software products such as the HERC system developed by Infineon, Technologies AG. Additionally, the program may be run on the databases generated using a variety of extraction tools, such as the Salve system developed by Infineon Technologies AG or the Vampire/Assura system available from Cadence Design Systems, Inc. Specific metal layer information derived from the runsets may be used to determine whether an extracted connection contains at least one segment through the required layer (e.g., metal 2). Additional details regarding the HERC system are disclosed in published U.S. patent applications “Method of Analyzing an Integrated Electric Circuit, Computer Program Utilizing the Method, Data Carrier Including the Method, and Method for Downloading the Program,” U.S. Publication No. 2003/0030445, and “Method for Checking an Integrated Electrical Circuit,” U.S. Publication No. 2003/0159120, both of which are incorporated by reference herein in their entirety. However, while reference is made herein to specific software and systems, the invention is not so limited and persons skilled in the art will recognize other software, systems and computer environments generally that are within the scope of the invention.

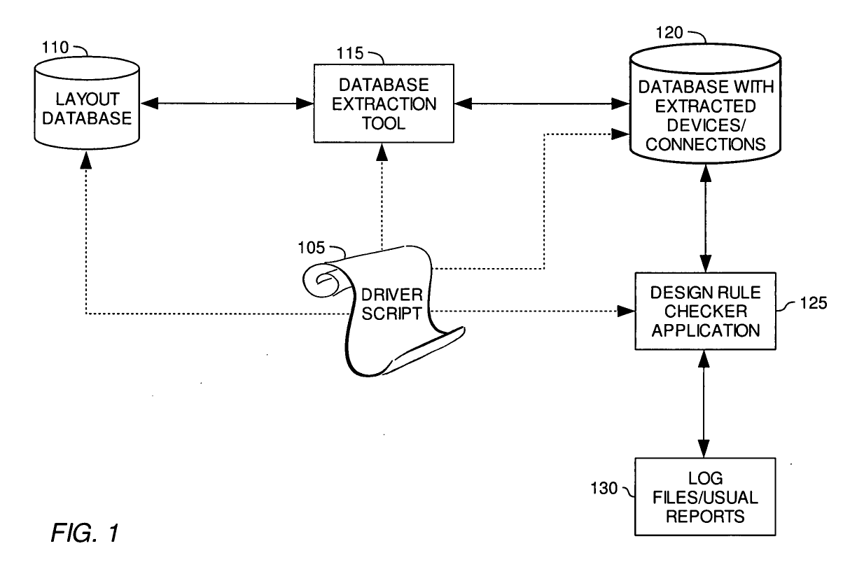

Referring now to the figures, FIG. 1 is a functional block diagram illustrating a system 100 for testing an IC design, according to one embodiment of the invention. Illustratively, the system 100 includes a layout database 110, a database extraction tool 115, extracted database 120, and a design rule checkers (DRC) application 125. In addition, the system 100 includes a driver script 105 that coordinates and controls the interaction between components of the system 100. After executing the driver script to test the design of a particular IC, rule checker 125 may be configured to produce log file 130 that identifies improper connections in the IC design. In one embodiment, the log file may include a text-based list of improper connections. Alternatively, more interactive log files are contemplated. For example, the log file 130 may include HTML code that may be rendered using a web-browser.

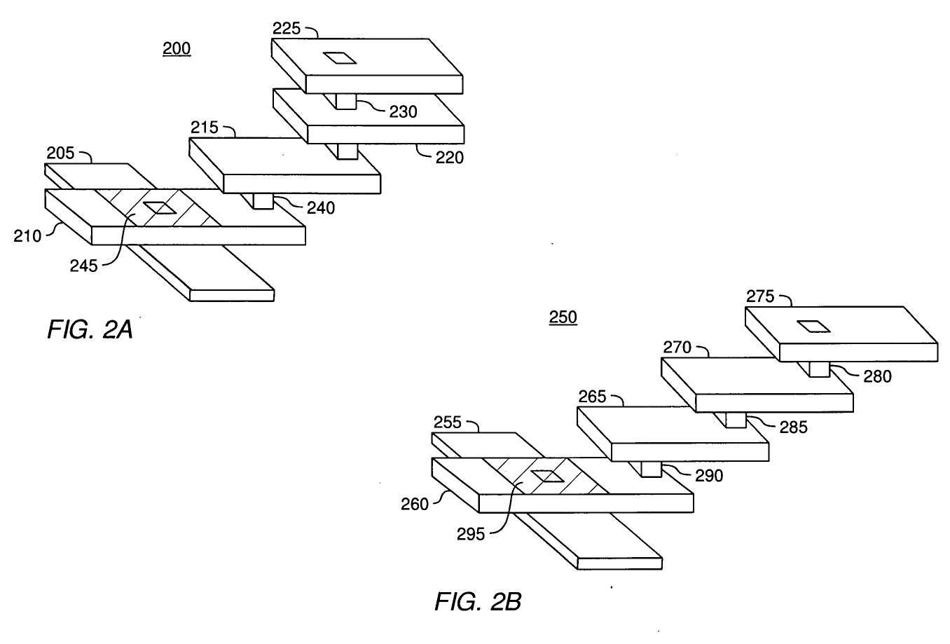

The following description uses an extracted layout of an exemplary IC design Illustrated in FIGS. 2-5. The IC shown in these figures, however, is substantially simplified, for illustrative reasons, as compared with commercially available integrated circuits. Illustratively, the metal 2 layer is used as the required layer that must exist for each connection between a bond pad and gate. In each of the FIGS. 2-5, the integrated circuit on the left side illustrates an IC design with an improper bond pad and gate connection. For comparison, an IC design with a correct bond pad and gate connection is illustrated on the right side of FIGS. 2-5.

FIGS. 2A and 2B illustrate a three-dimensional representation of a first IC 200 (FIG. 2A) and second IC 250 (FIG. 2B). The representation of the first IC 200 and second IC 250 shown in FIG. 2A and FIG. 2B corresponds to an image simulated on a computer system that is generated using a regular extraction of the IC designs of the first IC 200 and second IC 250 stored in layout database 110. The polygons at each individual layer are generated during the same fabrication step. That is, the individual layers are produced one after another during the manufacturing process.

The first IC 200 is divided into a plurality of layers. As illustrated, the first IC 200 is divided into a raw gate layer polygon 205, a metal 0 layer polygon 210, a metal 1 layer polygon 215, a metal 2 layer polygon 220 and a pad layer polygon 225. In addition, the metal 2 layer polygon 220 is connected to the metal 1 layer polygon 215 by connection segment 230. The metal 1 layer polygon 215 is connected to the metal 0 layer polygon 210 by connection segment 240. Also, the metal layer 0 polygon 210 is connected to the raw gate layer 205 polygon by connection segment 245.

Similarly, second IC 250 is also divided into a plurality of layers. The second IC includes a raw gate layer polygon 255, a metal 0 layer polygon 260, a metal 1 layer polygon 265, a metal 2 layer polygon 270 and a pad layer polygon 275. The metal 2 layer polygon 270 is connected to the metal 1 layer polygon 265 by connection segment 285. The metal 1 layer polygon 265 is connected to the metal 0 layer polygon 260 by connection segment 290. Also, the metal layer 0 polygon 210 is connected to the raw gate layer polygon 255 by connection segment 295.

In addition, the bond pad layer polygon 275 is connected to the metal 2 layer polygon 270 using connection segment 280. Contrast this connection with the connection between pad layer polygon 225 and metal 2 layer polygon 220: the connection segment 230 directly connects the bond pad layer polygon 225 to the metal 1 layer polygon 215. Thus, this connection is improper as the connection is not routed through a metal 2 layer connection segment (i.e. the metal two layer does not form part of the connection path). In one embodiment, this improper bond pad connectivity is detected and included in log file 130 by executing driver script 105 against the extracted layout of IC 200.

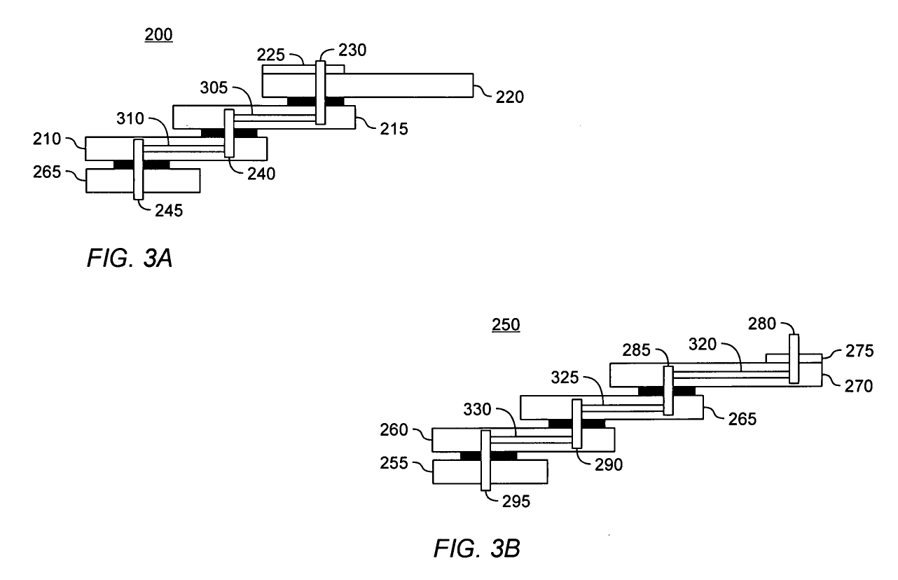

FIGS. 3A and 3B illustrate a two-dimensional plan view of the first IC 200 and second IC Circuit 250, first illustrated in FIGS. 2A and 2B, according to one embodiment of the invention. Again, the IC 200 includes an improper bond pad and gate connection, and IC 250 illustrates a properly routed connection between a bond pad and gate. In addition to the polygon layers and connection segments illustrated in FIGS. 2A, the plan view of IC 200 illustrated in FIG. 3A includes connection segments 305 and 310. Similarly, the plan view of IC 250 illustrated in FIG. 3B includes the polygon layers and connection segments illustrated in FIG. 2B along with the connection segments 320, 325 and 330. These connection segments illustrate the connectivity in IC 200 and 250 from pad layer polygons 225 and 275 to the gate layer polygons 245 and 255, respectively.

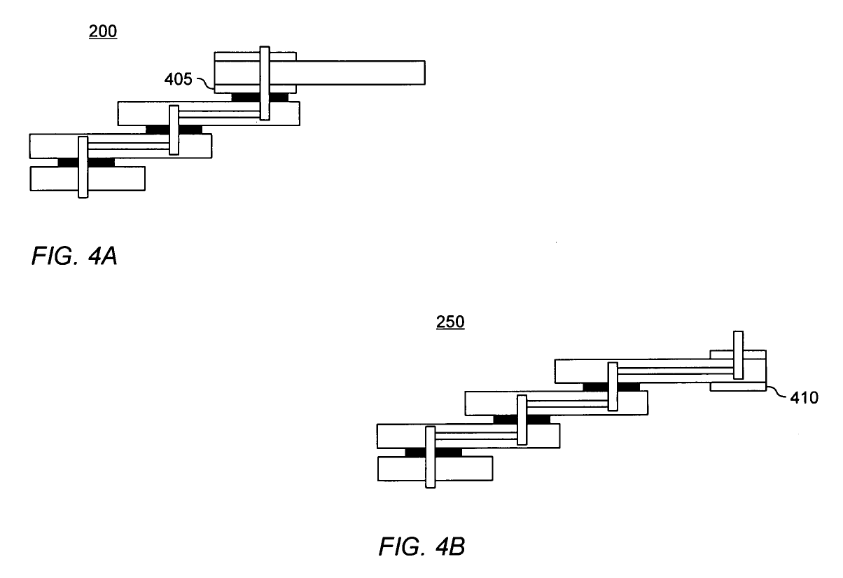

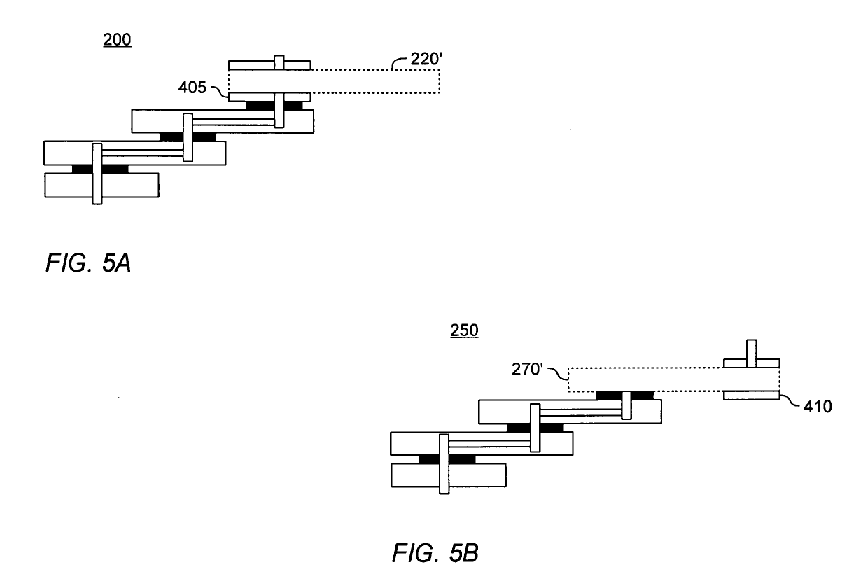

In one embodiment, the driver script 105 is configured to invoke the database extraction tool 115 to generate the regular extractions of IC 200 and 250 illustrated in FIGS. 3A and 3B. After the regular extraction of the IC being analyzed is completed, the driver script 105 may be further configured to invoke the DRC application 125 (e.g., the HERC system developed by Infineon, Technologies AG). The DRC application 125 executes the additional runsets required to detect any improper connections between the extracted bond pads and gates of the IC being analyzed. For example, any connections between a bond pad and a gate that is not routed through a metal 2 layer segment may be detected. FIGS. 4 and 5 illustrate the operations of these additional runsets on the representations of IC 200 and 250 generated by the extraction tool 115 and DRC application 125.

In one embodiment, the process of detecting improper bond pad connectivity includes executing additional runsets that add an additional layer to the extracted layout (illustrated in FIGS. 4A and 4B) and then removing the required layer from the extracted layout (illustrated in FIGS. 5A and 5B). The additional layer is used to test whether gate connectivity exists after the required layer is removed from the layout. After being removed, if a connection remaining connections between the bond pad layer and the added layer remains, then the connection is improper. An indication of any such connections may then be included in log file 130, allowing a designer to quickly identify and redesign these portions of the IC being analyzed.

Turning first to FIGS. 4A and 4B, illustrating a modified view of the IC designs first illustrated in FIGS. 3A and 3B, the extracted layout of the first IC 200 and the second IC 250 is shown. The layouts of FIGS. 4A and 4B are illustrated after being modified by a runset that inserts an additional layer (labeled as the myPad layer for convenience) into the extraction. In FIG. 4A, IC 200 includes myPad layer polygon 405 and in FIG. 4B, IC 250 includes myPad layer polygon 410. MyPad layer polygons 405 and 410 are added as a layer directly below the metal 2 layer. In one embodiment, this additional layer may be added by invoking the extraction tool 115 with a command such as “myPad=geomAnd (M2, PadLayer)” and then connection statement “Extend ConnectlList (via(C2, myPad))”. The actual commands used will depend on the syntax of the extraction tool 115. In this illustrative embodiment, the commands are modeled after the syntax of the Assura verification tool available from Cadence. Additionally, the commands to create the myPad layer may be part of driver script 105, or may be issued by a designer interacting with the extraction tool 115 directly.

FIGS. 5A and 5B illustrate a second, modified view of the IC extractions illustrated in FIGS. 4A and 4B. In FIGS. 5A and 5B, the metal 2 layer is removed from the extraction completely. Thus, the metal 2 layer polygon 220 of IC 200 and the metal 2 layer polygon of IC 250 are illustrated using dashed lines (polygons 220′ and 270′) to represent their absence from the extraction. The representations of IC 200 and IC 250 with the additional myPad layer and the removed metal 2 layer may now be checked for improper bond pad connectivity. In FIG. 5A, IC 200 includes a connection between the mypad layer polygon 405 and the raw gate polygon 205. The connection includes connection segments 230, 305, 240, 310, and 245. Because the connection exists, even without the metal 2 layer, this design is improper and will be logged in log file 105. In contrast, in FIG. 5B, IC 250 no longer has a connection between the mypad layer polygon 410 and raw gate polygon 255. Accordingly, this connection represents a correct design. In other words without the connection provided by the removed metal 2 layer polygon 270 (namely, connection segment 320), the bond pad is not connected to a gate.

In one embodiment, the connectivity between the gates and the bond pads of the modified extraction are tested using a runset executed by rule check application 125. Illustratively, Table 1 includes a rule set configured for the HERC rule checker developed by Infineon Technologies AG. This rule set tests bond pad connectivity against the extracted ICs 200 and 250, as illustrated in FIGS. 5A and 5B. The actual commands used, however, will depend on the syntax of the particular rule checker application 125.

TABLE I
Rule Check for Improper Bond Pad Connectivity

| | |
|---|---|
| 001 | ErcRules ( |

| | |
|---|---|
| 002 | reportNet ( |
| 003 | structures |

| | |
|---|---|
| 004 | pinType != “powernet” |
| 005 | remove (“M2”) |
| 006 | condition including (“myPad”, “raw_gates”) |
| 007 | title “Non power pad direct connected to gate |

without M2”

| | |
|---|---|
| 008 | ); reportNet |

| | |
|---|---|
| 009 | ); ercRules |

The rule set illustrated by Table 1 may be used to test each bond pad present in the extracted design layout of an integrated circuit. Lines 004, 005, and 006 test the connectivity of a bond pad. First, line 004 tests whether the bond pad being considered is identified in the extraction as being part of a power net. If so, the bond pad layer may properly be connected to a gate even without being routed through a metal 2 layer. Second, line 005 removes the metal 2 layer from the extracted IC. Third, line 006 evaluates the condition of whether a connection still exists between the myPad layer and the raw gates layer. If so, the bond pad being considered is included in a report of improperly connected bond pads. The rule check of Table 1 may be repeated for each bond pad present in the layout of an IC.

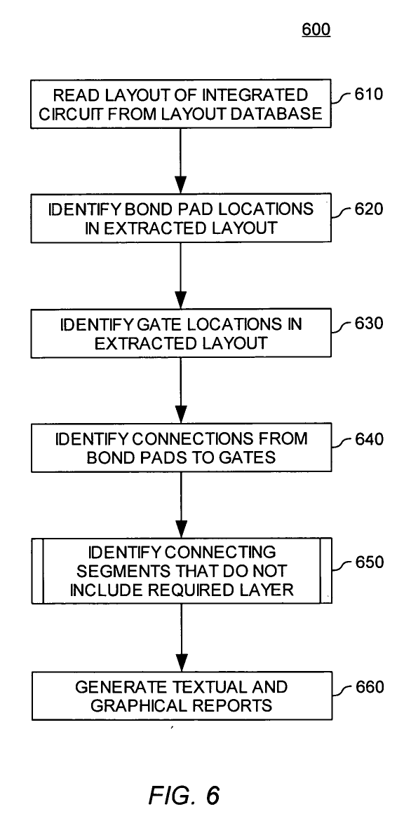

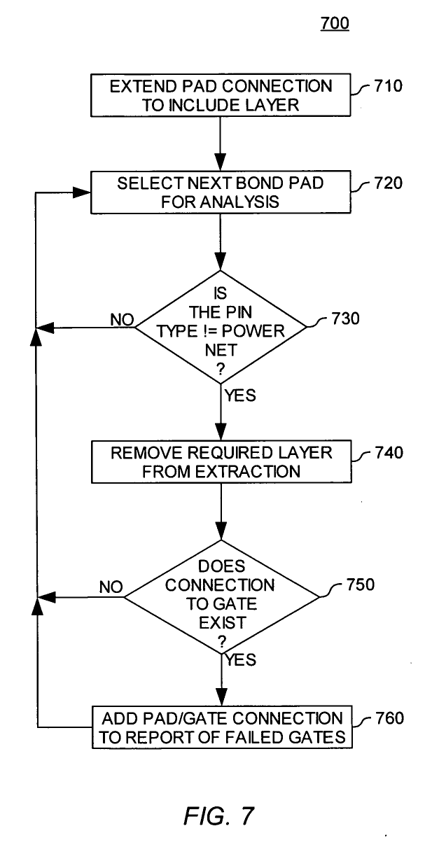

FIG. 6 illustrates a method 600 for testing the design of an IC, according to one embodiment of the invention. The method 600 begins at step 610 when the database extraction tool 115 is used to read the layout (e.g. IC 200 or 250) from layout database 110. At step 620, the bond pad locations in the extracted layout are determined. For example, a runset may be used to analyze the extracted layout to identify the bond pad structures. At step 630, the gate locations for the extracted layout are determined. Once the relevant structures of the IC are identified, the connections between the bond pads and gates are identified at step 640. In one embodiment, steps 620, 630, and 640 may be performed using a database extraction tool, either through driver script 105 or through a designer interacting with the extraction tool 115 directly. At step 650, the connecting segments are analyzed to identify connections between a bond pad and gate that lack a connection routed through the required layer (e.g., metal 2). The step of determining improper connectivity is further illustrated in FIG. 7.

After any improper bond pad connectivity is detected, at step 660 a report is generated and made available to the designer. The report identifies bond pads that with a connection to a gate that are not being routed over the required layer.

FIG. 7 illustrates a method 700 for detecting improper bond pad connectivity present in the design of an IC, according to one embodiment of the invention. The method 700 .begins at step 710 where the extracted layout of the IC being tested is extended to include an additional layer directly below the layer that is required for proper connectivity. For example, as illustrated in FIGS. 4A and 4B, the “mypad” layer is interpolated between the metal 2 layer and metal 1 layer of ICs 200 and 250 using “mypad” layer polygons 405 and 410, respectively. At step 720, a bond pad is selected for analysis. At step 730, if the selected bond pad is part of a power net, then the method returns to step 720 and selects a new bond pad for analysis. Otherwise, at step 740, the required layer is removed from the extraction. For example, FIGS. 5A and 5B illustrate ICs 200 and 250 with the metal 2 layer removed. At step 750, the modified extraction is analyzed to determine whether a connection between the layer added at step 710 and a gate of the IC still exists. If so, the bond pad selected at step 720 is improperly connected to the gate because it lacks a connection segment routed through the required layer (e.g., the connection between mypad layer 405 and raw gate layer 225 of IC 200). At step 760, if the selected bond pad is improperly connected, then it is added to a report of improperly connected bond pads. The method steps 720 through 760 may be executed for each bond pad included in the design of an integrated circuit.

Once the IC is analyzed, according to an embodiment of the present invention, any flaws detected in the bond pad connectivity may be corrected.

While the foregoing is directed to embodiments of the present invention, other and further embodiments of the invention may be devised without departing from the basic scope thereof, and the scope thereof is determined by the claims that follow.

What is claimed is:

1. A method for analyzing bond pad connectivity in the design of an integrated circuit, comprising:
retrieving the design for the integrated circuit from a layout database;
identifying the bond pads and gates included in the design of the integrated circuit;
determining the connections between the bond pads and the gates;
determining whether a connection between a particular gate and a particular bond pad lacks a connection segment routed over a required layer.

2. The method of claim 1, further comprising, generating a report identifying the particular bond pad and particular gate that are connected without a connection over the required layer.

3. The method of claim 1, wherein the required layer comprises a second metal layer of the integrated circuit.

4. The method of claim 1, wherein determining whether the connection between a particular gate and the particular bond pad lacks the connection segment routed over the required layer, comprises:
extending the design of the integrated circuit to include an additional layer interpolated between the required layer and a layer immediately below the required layer;
selecting the particular bond pad for analysis;
removing the required layer from the design of the integrated circuit;
determining whether a connection path exists between the additional layer and the particular bond pad in the design of the integrated circuit, after the required layer is removed; and
if so, generating a report indicating an improper connection for the particular bond pad.

5. The method of claim 4, wherein the required layer comprises a second metal layer of the integrated circuit.

6. The method of claim 4, wherein selecting the particular bond pad for analysis comprises selecting only bond pads that are not identified by the design layout as belonging to a user defined net.

7. The method of claim 6, wherein the user defined net comprises a power net.

8. A computer readable medium, containing a program which, when executed on a computer system, performs an operation for analyzing bond pad connectivity in the design of an integrated circuit, comprising:
retrieving the design for the integrated circuit from a layout database;
identifying the bond pads and gates included in the design of the integrated circuit;
determining the connections between the bond pads and the gates; and
determining whether a connection between a particular gate and a particular bond pad lacks a connection segment routed over a required layer.

9. The computer readable medium of claim 8, further comprising, generating a report indicating an improper connection for the particular bond pad present in the design of the integrated circuit.

10. The computer readable medium of claim 8, wherein the required layer comprises a second metal layer of the integrated circuit.

11. The computer readable medium of claim 8, wherein the program comprises a driver script configured to interact with a layout database and a design rule checker application.

12. The computer readable medium of claim 8, wherein determining connections between a particular gate and a particular bond pad that lack a connection routed over a required layer, comprises:
extending the design of the integrated circuit to include an additional layer interpolated between the required layer and a layer immediately below the required layer;
selecting the particular bond pad for analysis;
removing the required layer from the design of the integrated circuit;
determining whether a connection path exists between the additional layer and the particular bond pad and
if so, including the particular bond pad in a report indicating improper connectivity.

13. The computer readable medium of claim 12, wherein the required layer comprises a second metal layer of the integrated circuit.

14. The computer readable medium of claim 12, wherein the program comprises a driver script configured to interact with a layout database and a design rule checker application.

15. The computer readable medium of claim 12, wherein selecting the particular bond pad for analysis comprises selecting only bond pads that are not identified by the design layout as belonging to a user defined net.

16. A method for analyzing the bond pad connectivity in the design of an integrated circuit, comprising:
executing a first runset configured to generate a regular extraction of an integrated circuit, from the design of the integrated circuit stored in a layout database;
executing a second runset configured to extract the bond pad and gate locations from the regular extraction;
executing a third runset configured to identify the connections between the bond pads and gates extracted by the second runset; and
executing a fourth runset configured to determine whether any of the connections between a particular bond pad and a particular gate lack a connection routed over a required layer.

17. The method of claim 16, wherein the required layer comprises a second metal layer of the integrated circuit.

18. The method of claim 16, wherein the runsets are executed by a driver script configured to interact with the layout database and a design rule checker application.

19. The method of claim 16, wherein the fourth runset is configured to (i) extend the design of the integrated circuit to include an additional layer interpolated between the required layer and a layer immediately below the required layer, (ii) select a particular bond pad for analysis, (iii) remove the required layer from the design of the integrated circuit, (iv) determine whether a connection path exists between the additional layer and the particular bond pad in the design of the integrated circuit after the required layer is removed; and (v) if so, generate a report indicating an improper connection for the particular bond pad present in the design of the integrated circuit.

20. The method of claim 19, wherein selecting the particular bond pad for analysis comprises selecting only bond pads that are not identified by the design layout as belonging to a user defined net.

21. A computer readable medium containing a program which, when executed on a computer system, performs an operation for analyzing bond pad connectivity in the design of an integrated circuit, comprising:
executing a first runset configured to generate a regular extraction of an integrated circuit, from the design of the integrated circuit stored in a layout database;
executing a second runset configured to extract the bond pad and gate locations from the regular extraction;
executing a third runset configured to identify the connections between the bond pads and gates extracted by the second runset; and
executing a fourth runset configured to determine whether any of the connections between a particular bond pad and a particular gate lack a connection routed over a required layer.

22. The computer readable medium of claim 21, wherein the program comprises a driver script configured to interact with a layout database and a design rule checker application.

23. The computer readable medium of claim 21, wherein the required layer comprises a second metal layer of the integrated circuit.

24. The computer readable medium of claim 21, wherein the runsets are executed by a driver script configured to interact with the layout database and a design rule checker application.

25. The computer readable medium of claim 21, wherein the fourth runset is configured to (i) extend the design of the integrated circuit to include an additional layer interpolated between the required layer and a layer immediately below the required layer, (ii) select a particular bond pad for analysis, (iii) remove the required layer from the design of the integrated circuit, (iv) determine whether a connection path exists between the additional layer and the particular bond pad in the design of the integrated circuit after the required layer is removed; and (v) if so, generate a report indicating an improper connection for the particular bond pad present in the design of the integrated circuit.

26. The computer readable medium of claim 25, wherein selecting the particular bond pad for analysis comprises selecting only bond pads that are not identified by the design layout as belonging to a a user defined net.

27. A computer system for identifying improper connectivity between a bond pad of and a gate in a design of an integrated circuit, comprising:
a layout database storing the design of the integrated circuit,
a database extraction tool;
a design rule checker application; and
a driver script configured to execute a plurality of runsets to determine whether any of the connections between a particular bond pad and a particular gate of the integrated circuit design lack a connection routed over a required layer.

28. The computer system of claim 27 wherein the plurality of runsets are configured to (i) extend the design of the integrated circuit to include an additional layer interpolated between the required layer and a layer immediately below the required layer, (ii) select a particular bond pad for analysis, (iii) remove the required layer from the integrated circuit design, (iv) determine whether a connection path exists between the additional layer and the particular bond pad in integrated circuit design, after the required layer is removed; and (v) if so, generate a report indicating an improper connection for the particular bond pad present in integrated circuit design.

29. A computer readable medium containing a program which, when executed on a computer system, performs an operation for analyzing bond pad connectivity in the design of an integrated circuit, comprising:
retrieving the design for the integrated circuit from a layout database;
identifying the bond pads and gates included in the design of the integrated circuit;
determining the connections between the bond pads and the gates;
determining whether a connection between a particular gate and a particular bond pad lacks a connection segment routed over a required layer, wherein the determining comprises:
extending the design of the integrated circuit to include an additional layer interpolated between the required layer and a layer immediately below the required layer;
selecting the particular bond pad for analysis;
removing the required layer from the design of the integrated circuit;
determining whether a connection path exists between the additional layer and the particular bond pad in the design of the integrated circuit after removing the required layer; and
if so, generating a report indicating an improper connection for the particular bond pad present in the design of the integrated circuit.
